(19) United States
(12) Patent Application Publication
(10) Pub. No.: US 2006/0076555 A1
(43) Pub. Date: Apr. 13, 2006

(54) DETECTION AND REPAIR SYSTEM AND METHOD

(76) Inventors: Meng-Chieh Liao, Hsinchu City (TW); Chi-Chung Chen, Taipei City (TW); Chien-Shou Liao, Taipei City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/162,980

(22) Filed: Sep. 30, 2005

(30) Foreign Application Priority Data
Sep. 30, 2004 (TW) 93129722

(51) Int. Cl. H01L 29/08

(52) U.S. Cl. 257/40

(57) ABSTRACT

A detection and repair system applied for organic light-emitting devices comprises a distance measuring unit, a processing controller, a detector and a high-energy radiation beam generator. The distance measuring unit automatically detects the location of the organic light-emitting device. The processing controller generates a first control signal for automatically adjusting the relative positions of the organic light-emitting device and the detector according to the detecting result of the distance measuring unit. The detector detects the locations of defects on the organic light-emitting device. The processing controller can then generates a second control signal according to the detected locations of defects. The radiation beam generator generates a high-energy radiation beam, which is used to isolate one of the defects, according to the second control signal. Furthermore, a detection and repair method applied for organic light-emitting devices is disclosed.

### CROSS-REFERENCE TO RELATED APPLICATION

This application claims the priority benefit of Taiwan application serial no. 93129722, filed on Sep. 30, 2004. All disclosure of the Taiwan application is incorporated herein by reference.

### BACKGROUND OF THE INVENTION

1. Field of Invention

The present invention relates to a detection and repair system and method thereof. More particularly, the present invention relates to a detection and repair system and method applied for detecting and repairing defects of the organic light-emitting panel or organic light-emitting devices.

2. Description of Related Art

Information telecommunication industry has been one of the main stream of industries in current time, more particularly, the development is focusing on a variety of portable telecommunication display devices. As the panel display device is the communication interface between people and information, its development is particularly important. The current technologies applied in the panel display devices include plasma display, liquid crystal display, inorganic electroluminescence display, light emitting diode, vacuum fluorescence display, field emission display and electro-chromic display, etc.

Comparing with other panel display devices, the organic electroluminescent panel or organic electroluminescent unit (hereinafter, generally called organic light-emitting device) has advantages such as, self light-emitting, no view angle, power saving, simple manufacture process, low cost, broad operation temperature range, high responding speed and full color. It has been great potential and hopefully to be the main stream of the next generation of panel display devices.

The organic light-emitting device is a product to display using the self light-emitting features of organic functional materials, which can be divided into two types of small molecule organic light-emitting device (SM-OLED) and polymer light-emitting device (PLED) according to different quantity of the molecules of the organic functional materials. The light-emitting structure comprises a pair of electrodes and an organic functional material layer disposed between the electrodes. When current flows through the two electrodes, the electron and electron hole will recombination and generate excitons in the organic functional material layer, accordingly, the organic functional material layer may generate different color light-emitting mechanism according to the feature of the material.

In the manufacturing process of the organic light-emitting devices, if some particulates are attached on the surface of the substrate that will be coated, the pixel surface of the afterward formed organic light-emitting devices may cause abnormal stack layer, further, may cause circuit-short problem between the two electrodes of the pixel of the organic light-emitting device, accordingly, the brightness of the entire device degrades and the quality and reliability of the organic light-emitting device are affected. Therefore, in order to make sure for the quality of the devices, the detection and repair for the organic light-emitting device are important subjects that can not be neglected.

In order to resolve the above problems, those skilled in the art usually perform the detecting and repairing process for the organic light-emitting devices, using a detection machine having an optical microscope and a repairing machine having a high-energy radiation beam generator.

As described above, the conventional detecting methods, by a scanning manner, uses a detection machine having an optical microscope to detect whether a defect exists in the pixel of the organic light-emitting device and further to locate the position of the defect. Thereafter, the organic light-emitting device with defect is moved into the repairing machine with high-energy light beam generator to be repaired for defect. And, the repair theory is: the defect detected by the detection machine is radiated by a high-energy radiation beam to isolate the defect by a contactless manner.

For the detection and repair method, when a defect is detected in the pixel of an organic light-emitting device, the organic light-emitting device must be again moved to the repair machine from the detection machine to perform the repair action. However, in actual operation, after the organic light-emitting device is moved to the repair machine from the detection machine, it is impossible to instantly perform the repair action for the defects of the organic light-emitting device, but have to search and locate the positions of the defects again, then start the repair actions for the detected defects in turn.

Moreover, although the particulates attached on the surface of the substrate may cause abnormal stack of the film layer in the organic light-emitting device after depositing the film layer, and may further cause circuit-short problem between the two electrodes of the pixel of the organic light-emitting device. However, when the particulate size is very small, the particulates will not cause the circuit-short problem between the two electrodes of the pixel of the organic light-emitting device although which may cause abnormal stack of the film layer in the organic light-emitting device. This kind of defect can be, in fact, neglected in actual application and need not to be repaired. However, the conventional detection method detects the defect of the organic light-emitting device by scanning using an optical microscope, but the method can not judge whether or not the defect has caused circuit-short between the two electrodes. As a result, all the detected defects must be repaired in the repair process. That is, the conventional technologies may scan, locate, rescan, relocate and repair all the existed defects, which may waste manufacture cost.

As above, how to detect and repair the defect of the organic light-emitting device is still one of the important issues in the current production of the organic light-emitting devices.

### SUMMARY OF THE INVENTION

Accordingly, the present invention is directed to provide a detection and repair system and method which can detect and repair the defects of the organic light-emitting device effectively.

Accordingly, in order to achieve the aforementioned objectives, the detection and repair system, applied for organic light-emitting device according to the present invention, comprises: a distance measuring unit, a processing controller, a detector and a high-energy radiation beam generator. In the present invention, the distance measuring unit automatically detects the location of the organic light-emitting device. The processing controller, connected with the distance measuring unit, generates a first control signal according to the detecting result of the distance measuring unit to automatically adjust a relative position between the detector and the organic light-emitting device. The detector detects the location of at least one defect on the organic light-emitting device, and the processing controller can then generate a second control signal according to the detected locations of defects. The high-energy radiation beam generator, connected with the processing controller, generates a radiation beam, according to the second control signal, to isolate one of the defects by focusing at the position of the defect.

Furthermore, a detection and repair method used for an organic light-emitting device is disclosed, including: automatically detecting the location of the organic light-emitting device using a distance measuring unit. A first control signal is generated by the processing controller connected with the distance measuring unit, according to the detecting result of the distance measuring unit. The relative position between the detector and the organic light-emitting device is automatically adjusted according to the first control signal. A bias voltage is applied on the detecting area of the organic light-emitting device. the location of at least one defect on the organic light-emitting device is detected by the detector. A second control signal is generated by the processing controller according to the detected locations of defects. A high-energy radiation beam, focusing on the location of the defect, is generated by a high-energy radiation beam generator according to the second control signal to isolate one of the defects.

Furthermore, the present invention further provides another detection and repair system, used in an organic light-emitting device, comprising: a processing controller, a detector and a high-energy radiation beam generator. In the present invention, the processing controller generates a first control signal according to the location of the organic light-emitting device. The detector detects the location of at least one defect on the organic light-emitting device. The processing controller can then generate a second control signal according to the information of the locations of the detected defects. The high-energy radiation beam generator, connected with the processing controller, generates a radiation beam according to the second control signal, and the radiation beam is focused on the location of the defect to isolate the defect.

As described above, when the detection and repair system and method of the present invention detects the locations of the defects, the relative location between the organic light-emitting device and the detector is first automatically adjusted, using the distance measuring unit and the processing controller. Then, a bias voltage is applied on the detecting area of the organic light-emitting device, and the location of the defect (for example, the location of the defect where generates glimmer phenomenon) on the organic light-emitting device is detected by the detector. Then, the defect location is isolated by the high-energy radiation beam, so that the present invention does not need two machines to complete the detection and repair, and also the organic light-emitting device can be automatically located. Accordingly, the manually operation error and human resource waste can be reduced. Therefore, the detection and repair system and method according to the present invention can detect and repair the defects of the organic light-emitting devices effectively.

In order to the make the aforementioned and other objects, features and advantages of the present invention comprehensible, preferred embodiments accompanied with figures are described in detail below.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic diagram of a detection and repair system, according to one embodiment of the present invention.

FIG. 2 is a schematic diagram of the detection and repair system as shown in FIG. 1, wherein, the distance between the organic light-emitting device and the detector is adjusted to a suitable distance.

FIG. 3 is schematic flow charts, showing the detection and repair method according to one embodiment of the present invention.

### DESCRIPTION OF THE PREFERRED EMBODIMENTS

The following will describe the detection and repair system and method according to one preferred embodiment of the present invention referring to accompanied figures, wherein, the same units will be described by the same reference numbers. What needs to be stated again is that the organic light-emitting device of the present invention comprises an organic light-emitting panel and an organic light-emitting unit.

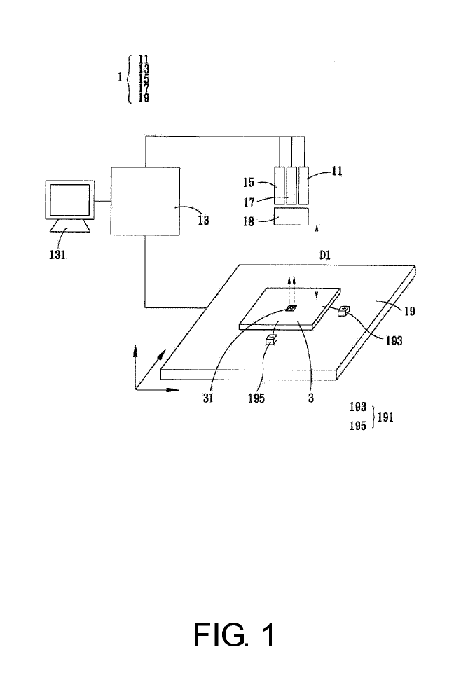

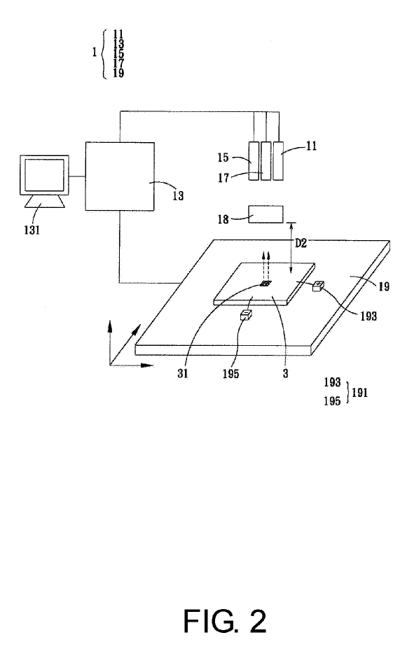

Referring to FIG. 1 and FIG. 2, the detection and repair system according to one embodiment of the present invention comprises a distance measuring unit 11, a processing controller 13, a detector 15, a high-energy radiation beam generator 17, an optical magnifier 18, and a support stage 19.

The distance measuring unit 11 automatically detects the location of the organic light-emitting device 3. The detector 15 detects the location 31 of at least one defect of the organic light-emitting device 3 through the optical amplifier 18. The processing controller 13 is connected with the distance measuring unit 11, the detector 15, the high-energy radiation beam generator 17 and the optical magnifier 18, respectively. The processing controller 13 generates a first control signal for automatically locating the organic light-emitting device 3 and the detector 15 according to the detecting result of the distance measuring unit 11. In the embodiment, the distance measuring unit 11 is a laser focuser, which emits a detection signal (for example, a laser radiation beam) to judge the original distance D1 between the organic light-emitting device 3 and the detector 15, accordingly, the detector 15 detects the detecting area of the organic light-emitting device 3 through the optical amplifier 18, so that the original distance D1 is the distance, as shown in FIG. 1, between the optical amplifier 18 and the organic light-emitting device 3. At this time, the detector 11 may transfer the detecting result to the processing controller 13, accordingly, so that the processing controller 13 can judge whether or not the original distance D1 is a suitable operation distance. If the original distance D1 is judged as an unsuitable operation distance by the processing controller 13, the processing controller 13 may generate a first control signal, by which the organic light-emitting device 3 and the detector 15 (or the optical amplifier 18) are controlled to move relatively until the distance between the organic light-emitting device 3 and the detector 15 (or the optical amplifier 18) is changed to be a suitable operation distance D2. Here, the detecting area of the organic light-emitting device 3 is detected by the detector 15 through the optical amplifier 18, so that the changed suitable distance D2 is the distance between the optical amplifier 18 and the organic light-emitting device 3, as shown in FIG. 2. Wherein, the processing controller 13 may be a computer, further including a display device 131 which is connected with the processing controller 13 and suitable for displaying the output image of the processing controller 13. Furthermore, the high-energy radiation beam generated by the high-energy radiation beam generator 17 can be a laser of predefined wavelength or a radiation beam with enough high energy to isolate the location of the defect.

As above, the distance measuring unit 11 is an apparatus to measure the distance. As the base to aid to correct the distance between the organic light-emitting device 3 and the detector 15 (or the optical amplifier 18), the distance measuring unit 11 uses laser, infrared, or supersonic as the signal of detecting distance. The signal can pass through the optical amplifier 18 or does not pass through the optical amplifier 18. And, the distance measuring unit 11 can be laser distance measuring unit, infrared distance measuring unit, or supersonic distance measuring unit. Moreover, in addition to that the distance between the organic light-emitting device 3 and the detector 15 (or the optical amplifier 18) is correct by the above distance measuring unit 11, an image comparison can also be applied to achieve the correction. The optical image can be obtained from the optical amplifier 18, and further the base is obtained for the processing controller 13 to correct the distance to the suitable correct distance D2 using image comparison.

Moreover, the optical amplifier 18 is an optical device, suitable for amplifying the image for detecting the defect image and isolating the defect location by the high-energy radiation beam, wherein the optical amplifier 18 may comprise a set of magnifying lenses with different magnifying powers or CCD optical couple devices. In the present invention, the high-energy radiation beam generated by the high-energy radiation beam generator 17 can locate and isolate the location of the defect by the optical amplifier 18. What needs to be noticed is that the diameter of the high-energy radiation beam generated by the high-energy radiation beam generator 1 7 can also be controlled in advance, so that the high-energy radiation beam can be directly focused on the location of the defect to isolate the location of the defect without using the optical amplifier 18.

Furthermore, the support stage 19 can support the organic light-emitting device 3, and the support stage 19 receives the first control signal and moves the organic light-emitting device 3 and the optical amplifier 18 relatively according to the first control signal. In the present invention, the support stage 19 can move the organic light-emitting device 3 or the optical amplifier 18 separately, or move the organic light-emitting device 3 and the optical amplifier 18 simultaneously, so that the distance between the organic light-emitting device 3 and the optical amplifier 18 can be automatically adjusted to the suitable distance D2. The support stage 19 is a three-axis movement and location stage. In addition, another three-axis movement controller can also be added on the optical amplifier 18 to adjust the distance between the organic light-emitting device 3 and the optical amplifier 18 to the suitable distance D2. It further controls the location of the defect detected by the detector 15 and control the aligning action of the optical amplifier 18.

Moreover, a power supplier 191 is disposed on the support stage 19. The power supplier 191 has a positive power terminal 193 and a negative power terminal 195, respectively. When the glimmer detector 15 would detect whether or not glimmer phenomenon exists, the organic light-emitting device 3 provides a negative bias voltage or a slight positive bias voltage by the power supplier 191. The bias voltage may cause the location of the defection in short problem to generate glimmer phenomenon, as the dotted line shown in FIG. 2. It is remarkable that, at the time, the processing controller 13 may generate a second control signal and a third control signal according to the defect location 31, and, the support stage 19 and the high-energy radiation generator 17 may act according to the third control signal and the second control signal generated by the processing controller 13, respectively. Wherein, the support stage 19 relatively moves the high-energy radiation generator 17 (and/or the optical amplifier 18) and the organic light-emitting device 3 according to the third control signal, so that the high-energy radiation generator 17 and/or the optical amplifier 18 can align with the defect location 31 of the organic light-emitting device 3. The high-energy radiation generator 17 may generate a high-energy radiation beam according to the second control signal, and the high-energy radiation beam focuses on the defect location 31 to isolate the defect location 31, so that the defect in the detecting area of the organic light-emitting device 3 can be repaired.

As described above, the detector 15 is a glimmer detector, and the defect location 31 may generate a glimmer phenomenon, so that the glimmer detector can detect the defect location 31 in which a glimmer phenomenon is generated. It should be noticed that the glimmer phenomenon generated by the defect location 31 may be generated by photon, infrared (IR), and/or thermal energy, and then the corresponding glimmer detector 15 can be photon detector, infrared detector, and thermal detector.

The following will describe the detection and repair method according to the preferred embodiment of the present invention in detail. For convenience of description, the figure numbers in the above embodiment will be quoted in the embodiment.

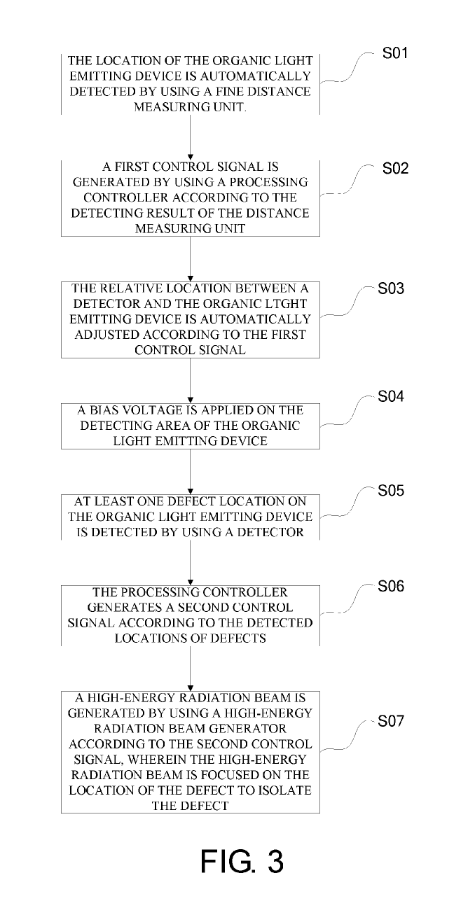

As shown in FIG. 3, the detection and repair method of the present invention includes the following steps: the location of the organic light-emitting device is automatically detected, using a distance measuring unit (step S01). A first control signal is generated, using a processing controller according to the detecting result of the distance measuring unit (S02). The relative location between a detector (for example, a glimmer detector) and the organic light-emitting device is automatically adjusted according to the first control signal (S03). A bias voltage is applied on the detecting area of the organic light-emitting device (S04). At least one defect location on the organic light-emitting device (generates glimmer phenomenon) is detected using a detector (S05). Then, a second control signal is generated, using a processing controller according to the detected locations of defects (S06). A radiation beam is generated, using a high-energy radiation beam generator according to the second control signal, wherein the high-energy radiation beam is focused on the location of the defect to isolate one of the defects (S07).

However, in order to have the high-energy radiation beam generated by the high-energy radiation beam generator 17 to be accurately focused on the effect location 31 of the organic light-emitting device 3, the processing controller 13 may generate a third control signal to move a support stage 19. And, the organic light-emitting device 3 is disposed on the support stage 19. Therefore, the detector 17 and the organic light-emitting device 3 can be moved relatively to adjust the relative locations, and further the high-energy radiation beam can be focused on the defect location 31 of the organic light-emitting device 3 accurately, or the high-energy radiation beam can be focused on the defect location 31 of the organic light-emitting device 3 accurately through an optical amplifier 18.

As described above, when the detection and repair system and method of the present invention detects the defection locations, the detection and repair system and method of the present invention automatically adjusts the relative locations between the organic light-emitting device and the (glimmer) detector (and optical amplifier), using the laser distance measuring unit and the processing controller in advance. Then, a bias voltage is applied on the detecting area of the organic light-emitting device, and the defect location (which generates glimmer) can be detected using the (glimmer) detector; then, the high-energy radiation beam can isolate the location of the defection, therefore, there may no need for two machines to complete the detection and repair. Furthermore, the detection and repair system and method of the present invention can automatically adjust and locate the organic light-emitting device, so that the manually operation error and the human resource waste can be reduced. Therefore, the detection and repair system and method of the present invention can directly judge the defect needed to be repaired while detecting the organic light-emitting device, and can automatically adjust the relative locations of the organic light-emitting device and the high-energy radiation beam generator. Not only the entire detection and repair method is simplified and the cost of the detection and repair is reduced, but also the defects of the organic light-emitting device can be detected and repaired effectively.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A detection and repair system, suitable for use on an organic light-emitting device, comprising:
a distance measuring unit, automatically detecting a location of the organic light-emitting device;
a processing controller, connected with the distance measuring unit, generating a first control signal according to a detecting result of the distance measuring unit;
a detector, connected with the processing controller, automatically adjusting a relative location between the detector and the organic light-emitting device and detecting a defect location of at least one defect on the organic light-emitting device, wherein the processing controller generates a second control signal according to the detected location of the at least one defect; and
a high-energy radiation beam generator, connected with the processing controller, generating a high-energy radiation beam to isolate one of the at least one defect according to the second control signal.

2. The detection and repair system as claimed in claim 1, further comprising:
a support stage, supporting the organic light-emitting device, wherein the processing controller generates a third control signal according to the detected defect location, wherein the support stage relatively moves the organic light-emitting device and the high-energy radiation generator according to the third control signal, and performs an alignment action with the organic light-emitting device aiming at the defect location, so that the high-energy radiation beam focuses on the defect location.

3. The detection and repair system as claimed in claim 2, wherein the support stage further comprises a power supplier, when the detector detects the defect location, a negative bias voltage or a slight positive bias voltage is applied on the organic light-emitting device by the power supplier.

4. The detection and repair system as claimed in claim 1, further comprising:
an optical amplifier, used for amplifying an image of the detecting area of the organic light-emitting device, wherein the detector is further connected with the optical amplifier and detects the defect location from the amplified image by the optical amplifier, and the high-energy radiation beam generator is further connected with the optical amplifier, so that the high-energy radiation beam is radiated through the optical amplifier.

5. The detection and repair system as claimed in claim 1, wherein the detector is a glimmer detector, and the defect location generates a glimmer phenomenon, so that the glimmer detector can detect the defect location in which the glimmer phenomenon is generated.

6. The detection and repair system as claimed in claim 5, wherein the glimmer detector is a photon detector, an infrared detector, or a thermal detector.

7. The detection and repair system as claimed in claim 1, wherein the distance measuring unit is a laser focuser.

8. A detection and repair method, suitable for use on an organic light-emitting device, comprising:
automatically detecting a location of the organic light-emitting device, using a distance measuring unit;
using a processing controller to generate a first control signal, according to a detecting result of the distance measuring unit;
automatically adjusting a relative location between the detector and the organic light-emitting device, according to the first control signal;
applying a bias voltage on the detecting area of the organic light-emitting device;
detecting a location of at least one defect on the organic light-emitting device by a detector;
generating a second control signal by the processing controller according to the detected locations of the at least one defect; and
generating a high-energy radiation beam by using a high-energy radiation beam generator according to the second control signal, for focusing on a location of the defect to isolate the at least one defect.

9. The detection and repair method as claimed in claim 8, further comprising:
using a support stage to support the organic light-emitting device, wherein the processing controller further generates a third control signal according to an information of the defect location, wherein the support stage relatively moves the organic light-emitting device and the high-energy radiation beam generator according to the third control signal, and performs an alignment action with the organic light-emitting device, aiming at the defect location, so that the high-energy radiation beam focuses on the defect location.

10. The detection and repair method as claimed in claim 8, wherein the bias voltage is a negative bias voltage or a slightly positive bias voltage.

11. The detection and repair method as claimed in claim 8, further comprising:
amplifying an image of the detecting area by using an optical amplifier, wherein the detector is further connected with the optical amplifier and detects the defect location from the amplified image by the optical amplifier, and the high-energy radiation beam generator is further connected with the optical amplifier, so that high-energy radiation beam is radiated through the optical amplifier.

12. The detection and repair method as claimed in claim 8, wherein the detector is a glimmer detector, and the defect location has a glimmer phenomenon, so that the glimmer detector can detect the defect location in which the glimmer phenomenon is generated.

13. The detection and repair method as claimed in claim 12, wherein the glimmer detector is a photon detector, an infrared detector, or a thermal detector.

14. The detection and repair method as claimed in claim 8, wherein the distance measuring unit is a laser focuser.

15. A detection and repair system, suitable for use on an organic light-emitting device, comprising:
a processing controller, generating a first control signal according to a location of the organic light-emitting device;
a detector, connected with the processing controller, wherein a relative location between the detector and the organic light-emitting device is automatically adjusted according to the first control signal, and a defect location of at least one defect on the organic light-emitting device is detected, and the processing controller generates a second control signal according to the detected defect location of the at least one defect; and
a high-energy radiation beam generator, connected with the processing controller, wherein the high-energy radiation beam generator generates a radiation beam according to the second control signal, and the radiation beam is focused on the defect location to isolate the at least one defect.

16. The detection and repair system as claimed in claim 15, further comprising:
a support stage, supporting the organic light-emitting device, wherein the processing controller generates a third control signal according to an information of the detected defect location, wherein the support stage relatively moves the organic light-emitting device and the high-energy radiation generator according to the third control signal, and performs an alignment action with the organic light-emitting device, aiming at the defect location, so that the high-energy radiation beam is focused on the defect location.

17. The detection and repair system as claimed in claim 16, wherein the support stage further comprises a power supplier, when the detector detects the defect location, a negative bias voltage is applied on the organic light-emitting device by the power supplier.

18. The detection and repair system as claimed in claim 16, wherein the support stage further comprises a power supplier, when the detector detects the defect location, a slight positive bias voltage is applied on the organic light-emitting device by the power supplier.

19. The detection and repair system as claimed in claim 15, further comprising:
an optical amplifier, amplifying an image of the detecting area, wherein the detector is further connected with the optical amplifier and detects the defect location from the amplified image by the optical amplifier, and the high-energy radiation beam generator is further connected with the optical amplifier, so that the high-energy radiation beam is radiated through the optical amplifier.

20. The detection and repair system as claimed in claim 15, wherein the detector is a glimmer detector, and the defect location has a glimmer phenomenon, so that the glimmer detector can detect the defect location in which the glimmer phenomenon is generated.

21. The detection and repair system as claimed in claim 20, wherein the glimmer detector is a photon detector, an infrared detector, or a thermal detector.

22. The detection and repair system as claimed in claim 15, further comprising:
a distance measuring unit, automatically detecting a location of the organic light-emitting device to provide the location of the organic light-emitting device detected by the distance measuring unit for the processing controller to generate a first control signal.

23. The detection and repair system as claimed in claim 22, wherein the distance measuring unit is a laser focuser.
